(19) United States
(12) Patent Application Publication
(10) Pub. No.: US 2019/0103153 A1
(43) Pub. Date: Apr. 4, 2019

(54) 3D CHIP STACK WITH INTEGRATED VOLTAGE REGULATION

(71) Applicant: Wei Huang, Frisco, TX (US)

(72) Inventor: Wei Huang, Frisco, TX (US)

(21) Appl. No.: 15/724,980

(22) Filed: Oct. 4, 2017

(51) Int. Cl. G11C 11/4074; H01L 27/06; G11C 5/14; H01L 25/065; H01L 23/00; H01L 23/48; H01L 27/02

(52) U.S. Cl. CPC G11C 11/4074; H01L 27/0688; G11C 5/147; H01L 25/0657; H01L 27/0207; H01L 24/17; H01L 24/48; H01L 23/481; H01L 24/16

(57) ABSTRACT

Various 3D chip stacks with integrated voltage regulation are disclosed. In one aspect, a semiconductor chip device includes a 3D chip stack that includes a first semiconductor chip that has a first integrated voltage regulator, a second semiconductor chip that has a second integrated voltage regulator and at least one additional semiconductor chip positioned between the first semiconductor chip and the second semiconductor chip. At least one of the first semiconductor chip and the second semiconductor chip is configured to supply a regulated voltage to the at least one additional semiconductor chip.

This invention was made with Government support under the PathForward program with Lawrence Livermore National Security, LLC (Prime Contract No. DE-AC52-07NA27344, Subcontract No. B620717 awarded by The United States Department of Energy). The Government has certain rights in this invention.

### BACKGROUND OF THE INVENTION

Many current integrated circuits are formed as multiple dice on a common wafer. After the basic process steps to form the circuits on the dice are complete, the individual die are singulated from the wafer. The singulated die are then usually mounted to structures, such as circuit boards, or packaged in some form of enclosure.

One frequently-used package consists of a substrate upon which a die is mounted. The upper surface of the substrate includes electrical interconnects. The die is manufactured with a plurality of bond pads. A collection of solder joints are provided between the bond pads of the die and the substrate interconnects to establish ohmic contact. After the die is mounted to the substrate, a lid is attached to the substrate to cover the die. Some conventional integrated circuits, such as microprocessors, generate sizeable quantities of heat that must be transferred away to avoid device shutdown or damage. The lid serves as both a protective cover and a heat transfer pathway.

Stacked dice arrangements involve placing or stacking one or more semiconductor chips on a base semiconductor chip. In some conventional variants, the base semiconductor chip is a high heat dissipating device, such as a microprocessor. The stacked chips are sometimes memory devices. In a typical conventional microprocessor design, the chip itself has a floor plan with various types of logic blocks, such as floating point, integer, I/O management, and cache blocks frequently interspersed among each other. The power densities of the blocks vary: some have relatively higher power densities and some have relatively lower power densities.

Power is supplied to the substrate or circuit board from some external power supply, which might be on or connected to a system board. The input power is typically produced by a voltage regulator on the system board. A 3.3 volt regulated voltage is typical of present-day power supplies for integrated circuits. However, conventional semiconductor chips often require power at different voltage levels. Providing a regulated step down voltage, from say a 3.3 volt input, can produce surprisingly high currents. For example, an integrated circuit operating at 100 watts and 1 volt may draw nearly 100 amps of current. Conventional voltage regulators usually include an inductor and switching logic to charge and discharge the inductor according to some algorithm.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary semiconductor chip device with a 3D chip stack;

FIG. 2 is a partially exploded pictorial view of the exemplary semiconductor chip device with a 3D chip stack;

FIG. 3 is a sectional view of FIG. 1 taken at section 3-3;

FIG. 4 is a schematic diagram of exemplary integrated voltage regulator architecture;

FIG. 5 is a sectional view like FIG. 3, but depicting exemplary heat spreader placement;

FIG. 6 is a sectional view like FIG. 5, but depicting alternate exemplary chip stacking;

FIG. 7 is a sectional view like FIG. 3, but depicting alternate exemplary passive device circuit placement; and

FIG. 8 is a pictorial view depicting an exemplary semiconductor chip device exploded from an exemplary electronic device.

### DETAILED DESCRIPTION

Stacked semiconductor chip devices present a host of design and integration challenges for scientists and engineers. Common problems include providing adequate electrical interfaces between the stacked semiconductor chips themselves and between the individual chips and some type of circuit board, such as a motherboard or semiconductor chip package substrate, to which the semiconductor chips are mounted. Another critical design issue associated with stacked semiconductor chips is thermal management. Most electrical devices dissipate heat as a result of resistive losses, and semiconductor chips and the circuit boards that carry them are no exception. Still another technical challenge associated with stacked semiconductor chips is supplying power, or more specifically, supplying regulated voltage power. Some conventional stack designs place a voltage regulator chip at the bottom of a stack of additional dice. But due to ohmic losses, there can be voltage droop associated with power delivered up to the upper dice. Some integrated circuits, such as memory chips, are relatively sensitive to regulated power supply voltage droop. If the droop exceeds a certain level, then the memory device can exhibit timing failures and other instabilities.

In accordance with one aspect of the present invention, a semiconductor chip device includes a 3D chip stack that includes a first semiconductor chip that has a first integrated voltage regulator, a second semiconductor chip that has a second integrated voltage regulator and at least one additional semiconductor chip positioned between the first semiconductor chip and the second semiconductor chip. At least one of the first semiconductor chip and the second semiconductor chip is configured to supply a regulated voltage to the at least one additional semiconductor chip.

In accordance with another aspect of the present invention, a semiconductor chip device includes a 3D chip stack that includes a first semiconductor chip that has a first integrated voltage regulator, a second semiconductor chip that has a second integrated voltage regulator and plural semiconductor chips positioned between the first semiconductor chip and the second semiconductor chip. The first semiconductor chip is configured to supply a first regulated voltage to at least one of the plural semiconductor chips closest to the first semiconductor chip and the second semiconductor chip is configured to supply a second regulated voltage to at least one of the plural semiconductor chips closest to the second semiconductor chip.

In accordance with another aspect of the present invention, a method of manufacturing a 3D chip stack includes stacking a first semiconductor chip, a second semiconductor chip and at least one additional semiconductor chip between the first semiconductor chip and the second semiconductor chip. The first semiconductor chip has a first integrated voltage regulator and the second semiconductor chip has a second integrated voltage regulator. At least one of the first semiconductor chip and the second semiconductor chip is configured to supply a regulated voltage to the at least one additional semiconductor chip.

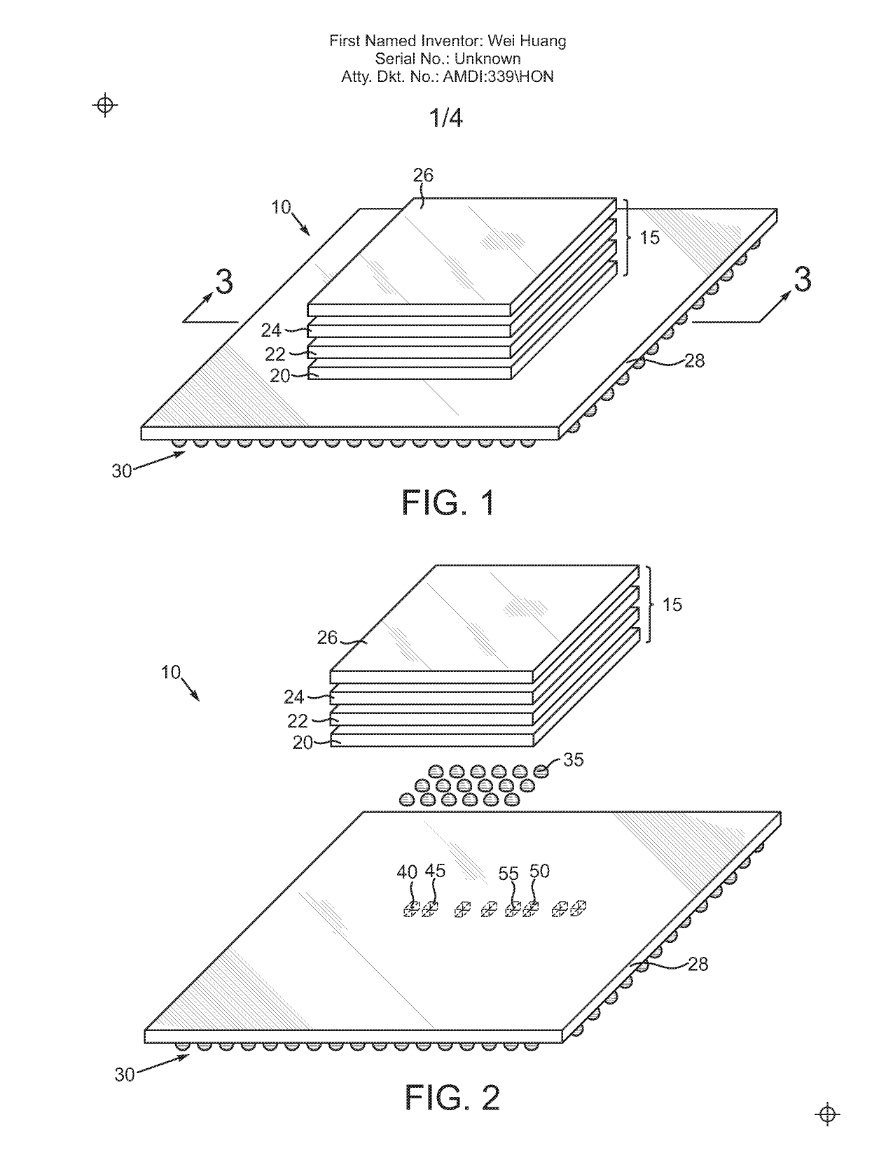

In the drawings described below, reference numerals are generally repeated where identical elements appear in more than one figure. Attention is now turned to FIGS. 1 and 2, which are a pictorial view and a partially exploded pictorial view, respectively, of an exemplary semiconductor chip device 10 that includes a stack 15 of semiconductor chips 20, 22, 24 and 26 mounted on a circuit board 28. The stack 15 is depicted with four semiconductor chips 20, 22, 24 and 26, but other numbers are envisioned. The semiconductor chips 22 and 24 can be any of a variety of different types of circuit devices used in electronics, such as, for example, interposers, microprocessors, graphics processors, combined microprocessor/graphics processors, application specific integrated circuits, memory devices or the like, and can be single or multi-core. The semiconductor chips 20, 22, 24 and 26 can be constructed of bulk semiconductor, such as silicon or germanium, or semiconductor on insulator materials, such as silicon-on-insulator materials or even insulator materials. Thus, the term “semiconductor chip” also contemplates insulating materials.

In this illustrated arrangement, the semiconductor chips 20 and 26 are constructed as integrated voltage regulators (IVRs) that include control and switching logic configured to selectively deliver currents to passive device circuits in or on the circuit board 28 and thereby provide regulated voltage power supplies to the semiconductor chips 22 and 24. As described in more detail below, the IVRs can be implemented with on die or off die passive device circuits.

The circuit board 28 can be a semiconductor chip package substrate, a circuit card, or virtually any other type of printed circuit board. Monolithic structures, such as those made of ceramics or polymers could be used. Alternatively, well-known build-up designs can be used. In this regard, the circuit board 28 can consist of a central core upon which one or more build-up layers are formed and below which an additional one or more build-up layers are formed. The core itself can consist of a stack of one or more layers. So-called “coreless” designs can be used as well. The layers of the circuit board 28 can consist of an insulating material, such as various well-known epoxies or other resins interspersed with metal interconnects. A multi-layer configuration other than buildup could be used. To interface electrically with another component, such as a circuit board or other device, the circuit board 28 can include plural I/O structures 30. The I/O structures 30 can be solder balls, solder bumps, conductive pillars, pins, lands or other types of interconnect structures.

The lowermost chip 20 in the stack 15 is interconnected to the circuit board 28 by way of plural interconnects 35. The interconnects 30 can be solder bumps, solder micro-bumps, conductive pillars or other interconnects. Well-known lead free solders, such as Sn—Ag, Sn—Ag—Cu or others can be used. Conductive pillars of copper, gold, aluminum, combinations of the these or the like can be used with or without solder caps.

As noted above, the semiconductor chips 20 and 26 selectively deliver currents to passive device circuits in or on the circuit board 28. A few exemplary passive device circuits 40, 45, 50 and 55, are shown (in dashed) in the circuit board 28. There can be more or less than what is shown.

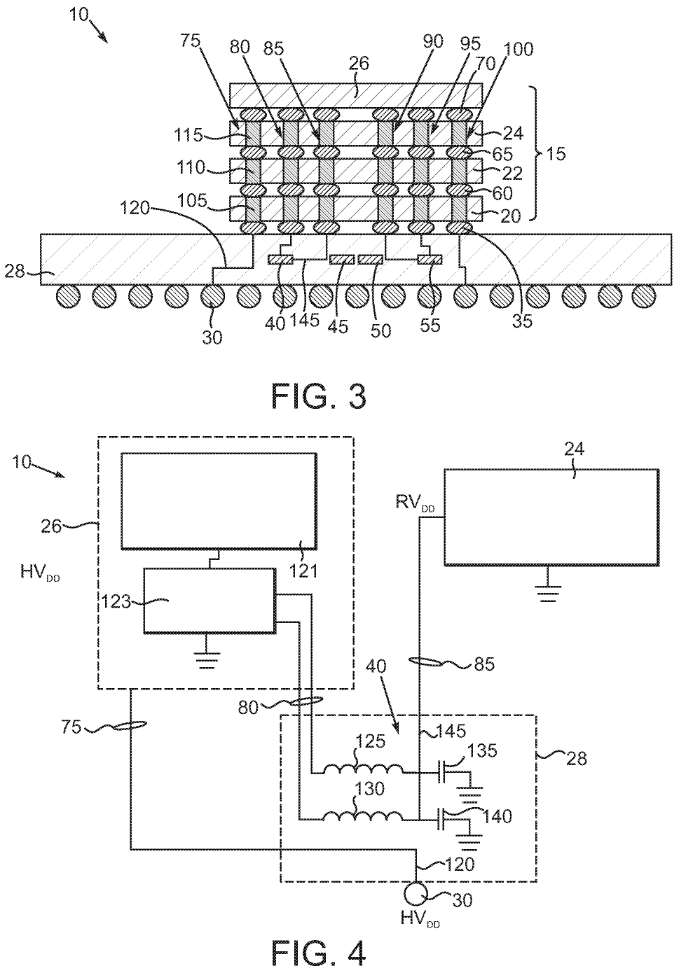

Additional details of the semiconductor chip device 10 may be understood by referring now also to FIG. 3, which is a sectional view of FIG. 1 taken at section 3-3. Note that section 3-3 passes through a portion of the circuit board 28 that includes the passive device circuits 40, 45, 50 and 55. As noted above, the semiconductor chip 20 can be electrically interfaced with the circuit board 28 by way of the plural interconnects 35. The semiconductor chips 22, 24 and 26 can be similarly interconnected by way of respective pluralities of interconnects 60, 65 and 70, which can be constructed with the same materials and of the same configuration as the interconnects 35. Power delivery voltage droop is a bigger potential problem for the more distal semiconductor chip 26 than for the lowermost semiconductor chip 20. Accordingly, low resistance pathways are provided between the IVRs of the semiconductor chips 20 and 26 and the circuit board based passive device circuits, namely, 40 and 55. In this regard, the various chips 20, 22 and 24 of the stack 15 are provided with plural dedicated power through stack through silicon vias (through stack TSVs) 75, 80, 85, 90, 95 and 100. The term “silicon” is used herein for convenience. The chips 20, 22, 24 and 26 could be constructed of materials in addition to or other than silicon. The through stack TSVs 75, 80, 85, 90, 95 and 100 each consist of plural TSVs. For example, the through stack TSV 75 consists of a TSV 105 in the semiconductor chip 20, a TSV 110 positioned in a semiconductor chip 22 and a TSV 115 positioned in the semiconductor chip 24 where the TSVs 105, 110 and 115 are electrically interconnected by way of some of the interconnects 60 and 65. Of course, the number of individual TSVs 105, 110 and 115 that make up a particular through stack TSV 75, 80, 85, 90, 95 and 100 will depend upon the number of chips that make up the stack 15. It should be understood that while the through stack TSVs 75, 80, 85, 90, 95 and 100 are dedicated to power conveyance, the stack 15 includes other TSVs for signal propagation and ground connections that are not visible. There of course can be many more through stack TSVs 75, 80, 85, 90, 95 and 100 in the stack 15 that are not visible in FIG. 3.

If the chips 20, 22, 24 and 26 are stacked together prior to mounting on the circuit board 28, then it is desirable for the interconnects 35 to have a lower reflow temperature than the interconnects 60, 65 and 70 to ensure that the reflow of the interconnects 35 during mounting of the stack 15 does not melt or otherwise damage the interconnects 60, 65 and 70. However, if the chip 20 is mounted first on the circuit board 28 followed by the chips 22, 24 and 26 in sequence, then the interconnects 35 should have the higher of the reflow temperatures.

As noted elsewhere herein, the interconnects 35, 60, 65 and 70 can take on a variety of alternative forms. For example, conductive pillars on each of two adjacent stacked chips can be thermal compression bonded. In another alternative arrangement, direction oxide bond and TSV last connection can be used. In this technique, facing sides of each two adjacent stacked chips each receive an oxide film. The oxide films are subsequently planarized using chemical mechanical polishing and then plasma treated to become hydrophillic. The oxide surfaces are next placed together and annealed to form a bond. Thereafter, one of the chips is thinned by backgrinding. TSV etches and metal deposition or plating are then used to establish TSVs in contact with various I/O pads of each chip. In yet another alternative arrangement, a hybrid bonding technique is used. Again, facing oxide films are formed on each of two adjacent chips. But conductive islands of copper or otherwise are interspersed in the oxide films. The chips are stacked with the respective conductive islands aligned vertically and a heating process in excess of about 200° C. is performed to bond the conductive islands together.

A variety of IVR architectures can be used to supply regulated voltage power. An exemplary architecture and a couple of exemplary electrical pathways associated with the chips 20, 22, 24 and 26 and the circuit board 28 will be described now in conjunction with FIG. 3 and also FIG. 4, which is a schematic diagram. A high voltage input HV_{DD} (from a source, such as another circuit board or device not shown) is delivered to one of the I/Os 30 and, by way of an electrical pathway 120, to the through stack TSV 75 and on to the semiconductor chip 26. The electrical pathway 120 can consist of plural interconnected conductor traces and vias depending upon the complexity of the circuit board 28. Optionally, a single through board via could be used as the pathway 120. The semiconductor chip 26 includes a further includes a controller 121 and switching logic 123 that, together with a passive device circuit, such as passive device circuit 40, make up an IVR. The switching logic 123 is electrically connected to the passive device circuit 40 by way of the through stack TSV 80. The passive device circuit 40 includes a pair of inductors 125 and 130 and a pair of capacitors 135 and 140 (and optionally more than two of each) that are positioned onboard the circuit board 28. The switching logic 123 includes two or more transistors to selectively pass current to a pair of inductors 125 and 130 of the passive device circuit 40. The common output of the inductors 125 and 130 is provided as an input to the semiconductor chip 24 as a regulated voltage RV_{DD} by way of the electrical pathway 145 in the circuit board 28 and the through stack TSV 85. The outputs of the inductors 125 and 130 are also tied to ground by way of respective capacitors 135 and 140. The capacitors 135 and 140 could be internal or external to the circuit board 28 and number more than two. Thus, the semiconductor chip 26 is operable to receive the voltage input HV_{DD} and, by way of the controller 121, the switching logic 123 and the passive device circuit 40, deliver the regulated voltage RV_{DD} as an input to the semiconductor chip 24. The controller 121, the switching logic 123 and the inductors 125 and 130 and capacitors 140 and 145 are configured to function as a well-known buck regulator. The controller 121 can be implemented on the semiconductor chip 26 or as a discrete component. The switching logic 123 can be similarly implemented on the semiconductor chip 26 or as a discrete component. Indeed the controller 121 and the switching logic 123 can be integrated into a single device that is integrated into the semiconductor chip 26. The through stack TSVs 75, 80 and 85 are configured with sizes (areas) large enough to ensure that any voltage droop from I/O 30 to the output of the through stack TSV 85 is small enough to maintain RV_{DD} within the operating limits of the semiconductor chip 24. The same types of connections and pathways are used for connecting up the semiconductor chip 20 with the passive device circuit 55 and the semiconductor chip 22. In other words, the semiconductor chip 20 includes the same type of circuitry depicted in FIG. 4 in terms of the controller 121, the switching logic 123 and the passive device circuit 40. It should be understood that multiple IVRs can be fabricated in or on a given chip, such as the semiconductor chips 20 and 26, and chained together.

It should be understood that any of the chips 20, 22, 24 and 26 in the stack 15 can tap power from a given through stack TSV 75, 80 etc. Thus, both of the semiconductor chips 20 and 26 (and their IVRs or portions thereof) can be electrically connected to and thus tap power from through stack TSV 75 or through stack TSV 100 etc. The same is true of the semiconductor chips 22 and 24.

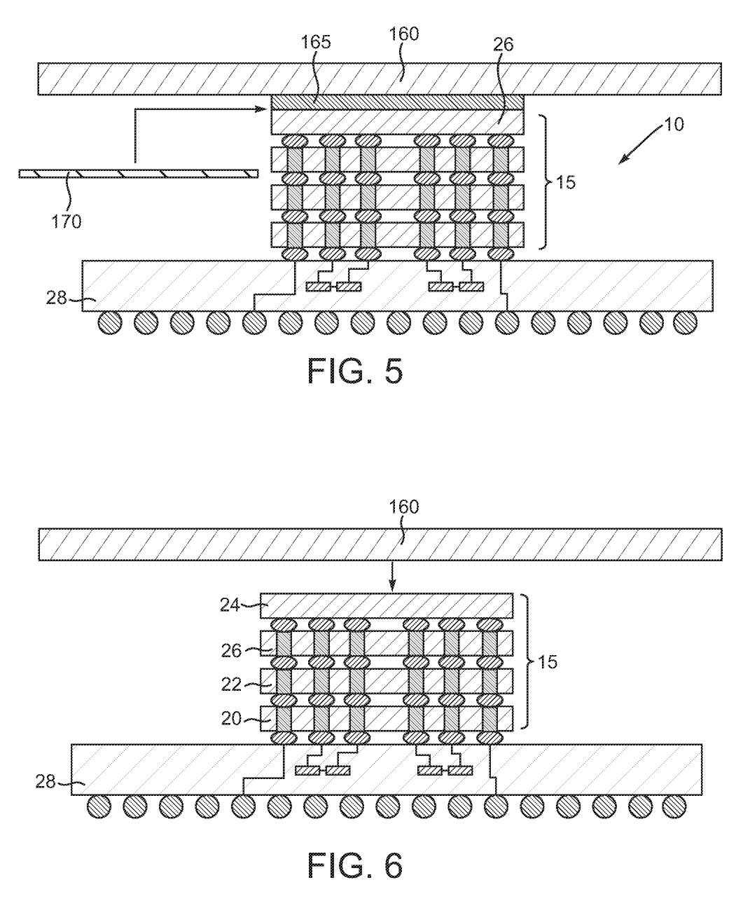

FIG. 5 depicts a sectional view like FIG. 3, but with the optional placement of a heat spreader or sink 160 on the stack 15 of the semiconductor chip device 10 and in thermal contact with the semiconductor chip 26. The heat spreader 160 could also thermally contact the circuit board 28. A thermal interface material 165 can be positioned between the semiconductor chip 26 and the heat spreader 160. The thermal interface material 165 can be a thermal grease or paste of silicone or other materials, a solder-type material, such as indium, bismuth or combinations of such or other materials. If the thermal interface material is a solder type, then an optional backside metallization 170 can be placed or otherwise fabricated on the semiconductor chip 26 to facilitate metallurgical bonding with a solder type TIM 165. The heat spreader 160 can be any of a myriad of configurations, such as plates, lids, top hat lids, bathtubs lids or others, and constructed of well-known heat spreader materials, such as copper, aluminum, stainless steel or the like. The optional backside metallization 170 can be a stack of an aluminum layer, a titanium layer, a nickel-vanadium layer and finally a gold layer, although these constituents could be varied.

It should be understood that the chips 20, 22, 24 and 26 of the stack 15 can be arranged in a variety of ways depending upon the thermal behavior and electrical requirements of the chips 20, 22, 24 and 26. Thus, in the illustrated arrangement, the semiconductor chips 20 and 26 implemented as IVRs can be placed symmetrically above and below the stack of logic chips 22 and 24. Furthermore, in this type of arrangement, the semiconductor chip 26 can provide regulated voltage for the chip 24 that it is closest to in the stack 15 and similarly the semiconductor chip 20 can provide a regulated voltage for the semiconductor chip 22, which is closest to it in the stack 15. However, it should be understood that this order of stacking can be varied. For example, and as shown in FIG. 6, the logic chip 24 is positioned in the top position and the semiconductor chip 26 implemented as an IVR can be positioned at the next lower vertical position on top of the logic chip 22. The semiconductor chip 20 can be positioned in the bottom most position as shown. Of course, if the stack 15 includes more than four chips and more than four IVRs, then other possible arrangements are envisioned. One technical advantage of positioning a chip, such as the chip 26 with an IVR, at the top most position immediately in contact with the heat spreader 160 is that at that position, the semiconductor chip 26 will tend to have a lower operating temperature and the same is true with regard to the next lower chip, the logic chip 24. Since the heat spreader 160 will keep the temperatures of the chips 24 and 26 lower than they might otherwise achieve, the resistance of the electrical pathways from the circuit board 28 to the semiconductor chips 24 and 26 will be lower than they might otherwise be if higher temperatures are seen at the chips 24 and 26. Differences in voltage between top and bottom IVR chips layers can also be compensated by putting more IVRs (or phases) in the top chip 26 shown in FIG. 5, such that the power delivery capability of the two chips 20 and 26 layers are similar.

A variety of methodologies can be used to select the number and placement of the chips 20 and 26 and in the stack 15. In one method, numerical modeling is used to estimate the power draw and temperature of each chip in the stack 15. With those estimated values in hand, the amount/area/size of through stack TSVs 75, 80, etc., and the number of IVRs can be calculated and the desired location(s) of each can be determined as well.

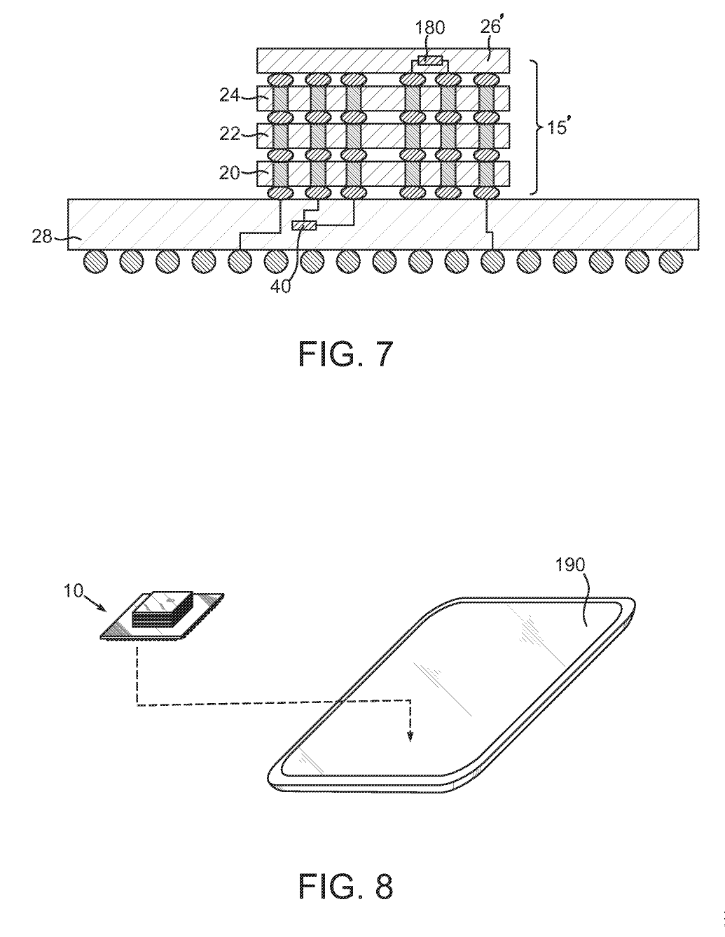

As noted above, positioning the inductors required for voltage regulation in the circuit board 28 has a technical advantage of providing for relatively large low resistance and therefore high current inductors due to the large geometries associated with the circuit board 28. However, the skilled artisan will appreciate that the required passive device circuits can be implemented on die. Thus, as used herein, the term IVR contemplates on die or off die passive device circuit placement. For example, FIG. 7 depicts a sectional view like FIG. 3 but of an alternate exemplary semiconductor chip device 10′, which includes a stack 15′ where the topmost semiconductor chip 26′ includes an on-die passive device circuit 180 that is designed to function like the circuit board-based passive device circuit 40 depicted in FIGS. 3 and 4 and described elsewhere herein. Of course, the semiconductor chip 26′ can include many more than merely a single passive device circuit 180 and any of the chips 20, 22 and 24 in the stack 15′ can include on-die inductors and capacitors as desired.

As depicted in FIG. 8, any of the disclosed embodiments of a semiconductor chip device 10 can be mounted in an electronic device 190. The electronic device 190 can be a tablet computer, a cell phone handset, or virtually any other electronic device that can utilize a circuit board.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A semiconductor chip device, comprising:
a 3D chip stack including a first semiconductor chip having a first integrated voltage regulator, a second semiconductor chip having a second integrated voltage regulator and at least one additional semiconductor chip positioned between the first semiconductor chip and the second semiconductor chip; and
whereby at least one of the first semiconductor chip and the second semiconductor chip is configured to supply a regulated voltage to the at least one additional semiconductor chip.

2. The semiconductor chip device of claim 1, wherein the first integrated voltage regulator comprises at least one inductor positioned on the first semiconductor chip.

3. The semiconductor chip device of claim 1, wherein the first integrated voltage regulator comprises at least one inductor positioned off the first semiconductor chip.

4. The semiconductor chip device of claim 1, comprising at least one through stack TSV electrically connecting the first semiconductor chip to the second semiconductor chip to deliver current input to the first semiconductor chip to the second semiconductor chip.

5. The semiconductor chip device of claim 4, wherein the through stack TSV comprises a first TSV in the first semiconductor chip, a second TSV in the second semiconductor chip, and at least one additional TSV in the at least one additional semiconductor chip connecting the first TSV to the second TSV.

6. The semiconductor chip device of claim 1, wherein each of the first integrated voltage regulator and the second integrated voltage regulator comprises a switching logic and a controller to control the switching logic.

7. The semiconductor chip device of claim 1, comprising a heat spreader positioned on the second semiconductor chip.

8. The semiconductor chip device of claim 1, comprising a circuit board, the stack being positioned on the circuit board.

9. A semiconductor chip device, comprising:
a 3D chip stack including a first semiconductor chip having a first integrated voltage regulator, a second semiconductor chip having a second integrated voltage regulator and plural semiconductor chips positioned between the first semiconductor chip and the second semiconductor chip; and
whereby the first semiconductor chip is configured to supply a first regulated voltage to at least one of the plural semiconductor chips closest to the first semiconductor chip and the second semiconductor chip is configured to supply a second regulated voltage to at least one of the plural semiconductor chips closest to the second semiconductor chip.

10. The semiconductor chip device of claim 9, wherein the first integrated voltage regulator comprises at least one inductor positioned on the first semiconductor chip.

11. The semiconductor chip device of claim 9, wherein the first integrated voltage regulator comprises at least one inductor positioned off the first semiconductor chip.

12. The semiconductor chip device of claim 9, comprising at least one through stack TSV electrically connecting the first semiconductor chip to the second semiconductor chip to deliver current input to the first semiconductor chip to the second semiconductor chip.

13. The semiconductor chip device of claim 12, wherein the through stack TSV comprises a first TSV in the first semiconductor chip, a second TSV in the second semiconductor chip, and at least one additional TSV in each of the plural semiconductor chips connecting the first TSV to the second TSV.

14. The semiconductor chip device of claim 9, wherein each of the first integrated voltage regulator and the second integrated voltage regulator comprises a switching logic and a controller to control the switching logic.

15. The semiconductor chip device of claim 9, comprising a heat spreader positioned on the second semiconductor chip.

16. The semiconductor chip device of claim 9, comprising a circuit board, the stack being positioned on the circuit board.

17. A method of manufacturing a 3D chip stack, comprising:
stacking a first semiconductor chip, a second semiconductor chip and at least one additional semiconductor chip between the first semiconductor chip and the second semiconductor chip, the first semiconductor chip having a first integrated voltage regulator, the second semiconductor chip having a second integrated voltage regulator; and
whereby at least one of the first semiconductor chip and the second semiconductor chip is configured to supply a regulated voltage to the at least one additional semiconductor chip.

18. The method of claim 17, comprising electrically connecting the first semiconductor chip to the second semiconductor chip with at least one through stack TSV to deliver current input to the first semiconductor chip to the second semiconductor chip.

19. The method of claim 17, comprising positioning a heat spreader positioned on the second semiconductor chip.

20. The method of claim 17, comprising mounting the 3D chip stack on a circuit board.
